(19) United States
(12) Patent Application Publication
(10) Pub. No.: US 2024/0186203 A1
(43) Pub. Date: Jun. 6, 2024

(54) SIDE-FILLING RESIN COMPOSITION, SEMICONDUCTOR DEVICE, METHOD FOR REMOVING SIDE-FILLING MEMBER, AND METHOD FOR FABRICATING THE SEMICONDUCTOR DEVICE

(71) Applicant: Panasonic Intellectual Property Management Co., Ltd., Osaka (JP)

(72) Inventors: Yusuke FUKAMOTO, Mie (JP); Yasushi YAMADA, Mie (JP)

(21) Appl. No.: 18/552,867

(22) PCT Filed: Mar. 28, 2022
(86) PCT No.: PCT/JP2022/014998

§ 371 Date: Sep. 27, 2023

(30) Foreign Application Priority Data
Apr. 5, 2021 (JP) 2021-064319

(51) Int. Cl. H01L 23/31; C08G 59/42; C08G 59/50; C08G 65/18; C08K 3/36; C08L 63/00; H01L 21/56; H01L 23/29

(52) U.S. Cl. CPC H01L 23/3185; C08G 59/42; C08G 59/5073; C08G 65/18; C08K 3/36; C08L 63/00; H01L 21/563; H01L 23/295; C08L 2203/206; H01L 2224/16225

(57) ABSTRACT

A side-filling resin composition is used to form a side-filling member to be interposed between a base member and a peripheral edge portion of a surface, facing the base member, of a mounted component that is surface-mounted on the base member. The side-filling resin composition contains a cationic polymerizable component and a photo-cationic polymerization initiator. The cationic polymerizable component includes at least one compound selected from an oxetane compound and an alicyclic epoxy compound. Proportion by mass of the oxetane compound and the alicyclic epoxy compound to a total content of the cationic polymerizable component is equal to or greater than 70% by mass.

### CROSS-REFERENCE OF RELATED APPLICATIONS

This application is the U.S. National Phase under 35 U.S.C. § 371 of International Patent Application No. PCT/JP2022/014998, filed on Mar. 28, 2022, which in turn claims the benefit of Japanese Patent Application No. 2021-064319, filed on Apr. 5, 2021, the entire disclosures of which applications are incorporated by reference herein.

### TECHNICAL FIELD

The present disclosure generally relates to a side-filling resin composition, a semiconductor device, a method for removing a side-filling member, and a method for fabricating the semiconductor device. More particularly, the present disclosure relates to a side-filling resin composition for use to reinforce mounted components such as semiconductor elements, a semiconductor device including a side-filling member made of the side-filling resin composition, a method for removing the side-filling member from a base member of the semiconductor device, and a method for fabricating the semiconductor device.

### BACKGROUND ART

In known semiconductor devices, each including a base member and a component mounted on the base member, the gap between the base member and the mounted component is supplied with a resin composition by either filling or applying the resin composition to reinforce connection between the base member and the mounted component. Examples of methods for reinforcing the base member and the mounted component by filling the gap between the base member and the mounted component with a resin composition include a method that uses underfilling and a method that uses side-filling.

According to the method that uses underfilling, the gap between the base member and the mounted component is entirely filled with the resin composition and then the resin composition is cured, thereby sealing the gap between the base member and the mounted component and reinforcing connection between the base member and the mounted component.

On the other hand, according to the method that uses side-filling, the resin composition is applied to only a part of the gap between the base member and the mounted component (e.g., only to peripheral end surfaces of the mounted component in plan view) and then cured, thereby reinforcing the gap between the base member and the mounted component (in particular, the peripheral edge portion of the surface, facing the base member, of the mounted component). Compared to the underfilling member, the side-filling member needs bonding the mounted component to the base member in a smaller area, thus allowing, if any defective components are found while the mounted components are being inspected or used, such defective mounted components to be easily removed from the board and replaced with non-defective ones. That is to say, the method that uses side-filling is excellent in so-called “repairability.” Nevertheless, the method that uses side-filling tends to cause a decline in reliability (e.g., reliability about heat resistance) of semiconductor devices.

For example, Patent Literature 1 discloses an epoxy resin composition which contains an epoxy resin, a curing agent, and an inorganic filler and which uses a thermosetting curing agent as a curing agent for the epoxy resin. Patent Literature 1 teaches making a side-filling member by interposing the epoxy resin composition between a semiconductor element and a board and thermally curing the epoxy resin composition.

### CITATION LIST

### Patent Literature

Patent Literature 1: JP 2013-102167 A

### SUMMARY OF INVENTION

An object of the present disclosure is to provide a side-filling resin composition, a semiconductor device, a method for removing a side-filling member, and a method for fabricating the semiconductor device, all of which make it easier to achieve not only excellent UV curability even when the resin composition is interposed by side filling in a part of the gap between a base member and a mounted component but also excellent repairability even when a side-filling member is formed.

A side-filling resin composition according to an aspect of the present disclosure is used to form a side-filling member to be interposed between a base member and a peripheral edge portion of a surface, facing the base member, of a mounted component that is surface-mounted on the base member. The side-filling resin composition contains a cationic polymerizable component (A) and a photo-cationic polymerization initiator (B). The cationic polymerizable component (A) includes at least one compound selected from the group consisting of an oxetane compound (A1) and an alicyclic epoxy compound (A2). Proportion by mass of the oxetane compound (A1) and the alicyclic epoxy compound (A2) to a total content of the cationic polymerizable component (A) of the side-filling resin composition is equal to or greater than 70% by mass.

A semiconductor device according to another aspect of the present disclosure includes a base member, a mounted component, and a side-filling member. The mounted component has been surface-mounted on the base member. The side-filling member is interposed between the base member and a peripheral edge portion of a surface, facing the base member, of the mounted component. The side-filling member is made of a cured product of the side-filling resin composition described above.

A method for removing a side-filling member according to still another aspect of the present disclosure includes removing the side-filling member of the semiconductor device described above from between a peripheral edge portion of the mounted component and the base member while heating the side-filling member to a temperature equal to or higher than 200° ° C.

A method for fabricating a semiconductor device according to yet another aspect of the present disclosure is designed to fabricate a semiconductor device including: a base member: a mounted component that is surface-mounted on the base member; and a side-filling member interposed between the base member and a peripheral edge portion of a surface, facing the base member, of the mounted component. The side-filling member is made of a cured product of the side-filling resin composition described above. The method for fabricating the semiconductor device includes an application step and a curing step. The application step includes applying the side-filling resin composition onto the base member and the peripheral edge portion of the surface, facing the base member, of the mounted component. The curing step includes curing the side-filling resin composition that has been applied. The curing step further includes irradiating the side-filling resin composition with light.

### BRIEF DESCRIPTION OF DRAWINGS

FIG. 1A is a schematic cross-sectional view illustrating a semiconductor device according to an exemplary embodiment of the present disclosure;

FIG. 1B schematically illustrates, on a larger scale, a part of the semiconductor device shown in FIG. 1A:

FIG. 2A is a plan view illustrating a first example in which a side-filling member is provided as an interposed member in a peripheral edge portion of a mounted component in the semiconductor device according to the exemplary embodiment of the present disclosure:

FIG. 2B is a plan view illustrating a second example in which a side-filling member is provided as an interposed member in a peripheral edge portion of a mounted component in the semiconductor device according to the exemplary embodiment of the present disclosure; and

FIG. 2C is a plan view illustrating a third example in which a side-filling member is provided as an interposed member in a peripheral edge portion of a mounted component in the semiconductor device according to the exemplary embodiment of the present disclosure.

### DESCRIPTION OF EMBODIMENTS

### 1. Overview

First, it will be described how the present inventors conceived the concept of a side-filling resin composition according to the present disclosure.

Examples of methods for filling, in a semiconductor device including a base member and a mounted component mounted onto the base member, the gap between the base member and the mounted component to reinforce connection between the base member and the mounted component include a method that uses side filling. As an exemplary resin composition for use in such a method that uses side filling, an epoxy resin composition as disclosed in Patent Literature 1 (JP 2013-102167 A) has been proposed.

The present inventors discovered that forming a cured product by sufficiently curing the epoxy resin composition of Patent Literature 1 makes it difficult, when the mounted components mounted on the board include any defective ones that need repairing, to perfectly remove the residue of the side-filling member from the board and the mounted components. That is to say, the present inventors discovered that poor repairability would be achieved in that case. In addition, the present inventors also found it difficult for the epoxy resin composition to achieve a high degree of curability using UV light.

Thus, to overcome such a problem, the present inventors carried out extensive research and development of an encapsulation resin composition. As a result, the present inventors finally conceived the concept of a side-filling resin composition according to the present disclosure.

A side-filling resin composition according to an exemplary embodiment is used to form a side-filling member 4 to be interposed between a base member 2 and a peripheral edge portion of a surface, facing the base member 2, of a mounted component 3 that is surface-mounted on the base member 2. The side-filling resin composition according to this embodiment contains: a cationic polymerizable component (A); and a photo-cationic polymerization initiator (B). The cationic polymerizable component (A) includes at least one compound selected from the group consisting of an oxetane compound (A1) and an alicyclic epoxy compound (A2). The proportion by mass of the oxetane compound (A1) and the alicyclic epoxy compound (A2) to the total content of the cationic polymerizable component (A) of the side-filling resin composition is equal to or greater than 70% by mass. Thus, even when a side-filling member 4 is formed by interposing, by the side-filling method, the side-filling resin composition according to this embodiment in a part of the gap between the base member 2 and the mounted component 3, excellent UV curability may still be imparted to the side-filling resin composition and excellent repairability may still be imparted to the side-filling member 4. As used herein, the “side-filling member” refers to a member made of a material for use to reinforce a mounted component such as a semiconductor element that is surface-mounted on a base member. In this embodiment, the side-filling member 4 is made of a cured product of a side-filling resin composition. It can also be said that the side-filling member 4 is a reinforcing member used to be interposed between the base member 2 and the peripheral edge portion of the surface, facing the base member 2, of the mounted component 3. As used herein, the “peripheral edge portion” of the surface, facing the base member 2, of the mounted component 3 may be the entire peripheral edges of the mounted component 3 in plan view or at least a part of the peripheral edges thereof, whichever is appropriate.

Although it is not exactly clear why these advantages are achieved by the side-filling resin composition according to this embodiment, the reason is presumably as follows. Specifically, adding the cationic polymerizable component (A) and the photo-cationic polymerization initiator (B) to a side-filling resin composition would impart UV curability to the side-filling resin composition. The oxetane compound (A1) and the alicyclic epoxy compound (A2) would both have their curing accelerated by an acid generated from the photo-cationic polymerization initiator (B) when irradiated with a UV ray. In addition, making the proportion by mass of the oxetane compound (A1) and the alicyclic epoxy compound (A2) to the total content of the cationic polymerizable component (A) equal to or greater than 70% by mass would impart a high degree of UV curability to the side-filling resin composition. The “UV curability” as used herein may be measured by the same evaluation method as the one that will be described later in the “2.3. UV curability” section of Examples and may be confirmed based on the results of the measurements.

In addition, the side-filling resin composition according to this embodiment may be cured simply when interposed between the base member 2 and the mounted component 3 and irradiated with light even without being heated, unlike the known thermosetting side-filling resin composition. This enables avoiding causing an excessive increase in adhesion strength between the base member 2 and the side-filling member 4 when the side-filling member 4 is formed out of the side-filling resin composition. This makes it easier, even when the side-filling member 4 formed on the base member 2 needs to be removed to replace any defective component of the semiconductor device 1, to remove residues of the side-filling member 4 from the base member 2 and the mounted component 3. Note that the side-filling member 4 on the base member 2 is removable by heating the side-filling member 4 to a temperature approximately as high as a solder melting temperature (of about 200° C.). Meanwhile, the side-filling member 4 is easily removable according to this embodiment partly because of the following action. Specifically, when the side-filling resin composition containing the cationic polymerizable component (A) and the photo-cationic polymerization initiator (B) is cured, acidic components produced as byproducts from the photo-cationic polymerization initiator (B) may be left in the cured product. Then, heating this cured product to a higher temperature causes the acidic components and the cured product to react with each other to thermally decompose the cured product. As a result, the physical properties of the cured product decline to make the cured product easily peelable from the base member. This is probably the reason why the side-filling resin composition according to this embodiment may impart excellent repairability to the side-filling member. As used herein, the “repairability” indicates how easily a cured product (which may be any one of an underfilling member or a side-filling member) of a resin composition in a semiconductor device 1 may be removed from the base member 2. The repairability of the cured product in the semiconductor device 1 may be checked by the method that will be described later in the “2.4. Repairability” section of Examples.

As can be seen, according to this embodiment, the cured product of the side-filling resin composition is easily removable by heating. Thus, the side-filling resin composition according to this embodiment makes the semiconductor device 1 easily repairable even if the semiconductor device 1 comes to have any defective components. In addition, the side-filling resin composition according to this embodiment may reinforce connection between the base member 2 and the mounted component 3 in the gap between the base member 2 of the semiconductor device 1 and the peripheral edge portion of the surface, facing the base member 2, of the mounted component 3 mounted on the base member 2.

More specifically, the side-filling resin composition is allowed to have these advantageous properties by appropriately adjusting the respective components of the composition to be described below.

### 2. Details

Next, components that may be included in the side-filling resin composition according to this embodiment and the properties of the side-filling resin composition will be described in greater detail.

A side-filling resin composition according to this embodiment contains a cationic polymerizable component (A) and a photo-cationic polymerization initiator (B). The cationic polymerizable component (A) includes at least one compound selected from the group consisting of an oxetane compound (A1) and an alicyclic epoxy compound (A2). The proportion by mass of the oxetane compound (A1) and the alicyclic epoxy compound (A2) to the total content of the cationic polymerizable component (A) is equal to or greater than 70% by mass. The side-filling resin composition according to this embodiment has a high degree of UV curability. This reduces the chances of the side-filling member 4 coming to have an uncured portion when the side-filling member 4 to be interposed in the gap between the base member 2 and the peripheral edge portion of the surface, facing the base member 2, of the mounted component 3 is formed in the semiconductor device 1 by irradiating the side-filling resin composition with light.

In the semiconductor device 1 including the side-filling member 4 made of a cured product of the side-filling resin composition according to this embodiment, the side-filling member 4 thereof may have excellent heat resistance and repairability. In particular, in the known art, when a reinforcing member is formed by the side filling method out of a thermosetting resin component in the presence of a curing agent, an additive such as a softening agent is added thereto to improve its repairability. In that case, however, addition of the softening agent tends to cause a decline in thermal properties such as heat resistance and thermal shock resistance of the semiconductor device 1. In contrast, the side-filling resin composition according to this embodiment allows the semiconductor device 1 including a cured product of the side-filling resin composition to have excellent thermal shock resistance. In addition, the side-filling member 4 may have excellent repairability even if no additive such as a softening agent is added thereto. Thus, according to this embodiment, even if the semiconductor device 1 comes to have any defective components, the cured product is easily removable by heating the side-filling resin composition and only defective parts are replaceable when repair is made to eliminate any defects caused.

The side-filling resin composition according to this embodiment has UV curability as described above. Therefore, the side-filling resin composition may shorten, compared to filling the gap between the base member 2 of the semiconductor device 1 and the mounted component 3 that is surface-mounted on the base member 2 with a thermosetting resin component and curing the thermosetting resin component, the takt time (e.g., the time it takes to form the cured product) when the peripheral edge portion of the surface, facing the base member 2, of the mounted component 3 is reinforced with the cured product of the side-filling resin composition. Furthermore, a cured product of the side-filling resin composition may be formed even if the side-filling resin composition is not heated to be cured, and therefore, the side-filling member 4 is less likely to be affected by the thermal history due to heating. Thus, the side-filling resin composition may not only reinforce the base member 2 and the peripheral edge portion, facing the base member 2, of the mounted component 3 by making the mounted component 3 less easily separable in the semiconductor device 1 but also reduce the chances of causing conduction failures in the semiconductor device 1.

In addition, the side-filling resin composition according to this embodiment may also reduce the chances of air bubbles being produced before and after the curing while the side-filling member 4 is being formed, compared to a composition including a lot of thermosetting resin components. This reduces the chances of producing voids in the cured product. Consequently, this reduces, even if the peripheral edge portion of the surface, facing the base member 2, of the mounted component 3 is reinforced with the side-filling resin composition, the chances of causing defects in the semiconductor device 1.

Therefore, reinforcing the base member 2 and the mounted component 3 with the side-filling resin composition interposed between the base member 2 and the peripheral edge portion of the surface, facing the base member 2, of the mounted component 3 that is surface-mounted on the base member 2 in the semiconductor device 1 enables forming the side-filling member 4 in a short time and reducing the chances of leaving a thermal history in the side-filling member 4. Consequently, the side-filling member 4 (reinforcing member) made of the side-filling resin composition is hardly warped and rarely produces voids.

### [Cationic Polymerizable Component]

The cationic polymerizable component (A) preferably contains a photo-cationic polymerizable compound, for example. The cationic polymerizable component (A) has the property of being cured by causing a polymerization reaction with an acid produced from the photo-cationic polymerization initiator (B). The cationic polymerizable component (A) preferably has, for example, the property of producing a ring-opening polymerization reaction under the presence of the photo-cationic polymerization initiator (B). In this embodiment, the cationic polymerizable component (A) includes at least one of the oxetane compound (A1) or the alicyclic epoxy compound (A2), each of which is included in a photo-cationic polymerizable compound. In this embodiment, in the cationic polymerizable component (A), the proportion by mass of the oxetane compound (A1) and the alicyclic epoxy compound (A2) to the total content of the cationic polymerizable component (A) is equal to or greater than 70% by mass. This enables imparting not only a high degree of UV curability to the side-filling resin composition but also an even higher degree of repairability to a cured product of the side-filling resin composition.

In addition, if the side-filling resin composition contains the photo-cationic polymerizable compound, high reliability will be achieved in a heat cycle when the base member 2 and the mounted component 3 are reinforced with the cured product of the side-filling resin composition in the semiconductor device 1. As used herein, the “heat cycle” refers to a temperature cycle in which heating and cooling are alternately repeated between a low temperature range (e.g., −40° C.) and a high temperature range (e.g., 125° C.).

In this embodiment, the cationic polymerizable component (A) includes at least one of the oxetane compound (A1) or the alicyclic epoxy compound (A2) and the proportion by mass of the oxetane compound (A1) and the alicyclic epoxy compound (A2) to the total content of the cationic polymerizable component (A) is equal to or greater than 70% by mass, as described above. This makes it easier to lower the viscosity of the side-filling resin composition compared to a situation where the side-filling resin composition includes only thermally polymerizable components. This reduces the chances of the side-filling resin composition coming to have increased viscosity even if the proportion of components such as the inorganic filler to be described later is increased in the side-filling resin composition. This makes it easier to adjust the coefficient of thermal expansion of the cured product to a low value, thus improving the thermal shock resistance of the semiconductor device 1 including a cured product of the side-filling resin composition. Consequently, the semiconductor device 1 may have a high degree of reliability in heat resistance.

In this embodiment, the cationic polymerizable component (A) includes at least one of the oxetane compound (A1) or the alicyclic epoxy compound (A2) and the proportion by mass of the oxetane compound (A1) and the alicyclic epoxy compound (A2) to the total content of the cationic polymerizable component (A) is equal to or greater than 70% by mass. The proportion by mass of the oxetane compound (A1) and the alicyclic epoxy compound (A2) to the total content of the cationic polymerizable component (A) is more preferably equal to or greater than 75% by mass, even more preferably equal to or greater than 80% by mass, and particularly preferably equal to or greater than 85% by mass. The upper limit of the proportion by mass of the oxetane compound (A1) and the alicyclic epoxy compound (A2) to the total content of the cationic polymerizable component (A) is not limited to any particular value but may be 100% by mass, for example.

The cationic polymerizable component (A) may include only the oxetane compound (A1) or only the alicyclic epoxy compound (A2). However, it is preferable that the cationic polymerizable component (A) include both the oxetane compound (A1) and the alicyclic epoxy compound (A2). If the cationic polymerizable component (A) includes both the oxetane compound (A1) and the alicyclic epoxy compound (A2), then the alicyclic epoxy compound (A2) exhibits a higher degree of photo-reactivity in an initial stage of reaction, which makes it easier to advance the reaction in an initial stage of the curing reaction. On the other hand, the oxetane compound (A1) has a lower reaction rate in the initial stage than the alicyclic epoxy compound (A2). However, as the concentration of the cured product is increased by the advancement of the curing reaction of the alicyclic epoxy compound (A2), the reactivity of the oxetane compound (A1) may be increased gradually. That is why the cationic polymerizable component (A) containing both the oxetane compound (A1) and the alicyclic epoxy compound (A2) makes it even easier to increase the UV curability of the side-filling resin composition.

The ratio of the oxetane compound (A1) to the alicyclic epoxy compound (A2) in the cationic polymerizable component (A) falls within the range from 1:0 to 0:1. The ratio of the oxetane compound (A1) to the alicyclic epoxy compound (A2) preferably falls within the range from 9:1 to 2:8 and more preferably falls within the range from 9:1 to 3:7.

The oxetane compound (A1) may be, for example, a compound having at least one oxetane skeleton in one molecule. Specifically, the oxetane compound (A1) may be at least one compound selected from the group consisting of, for example, 3-ethyl-3-hydroxymethyl oxetane, 2-ethylhexyl oxetane, 3-ethyl-3-(2-ethylhexyloxymethyl) oxetane, 3-ethyl-3-(cyclohexyloxy) methyl oxetane, and 3-ethyl-3-(phenoxymethyl) oxetane.

The alicyclic epoxy compound (A2) is a compound which has at least one epoxy group in a molecule and in which two carbon atoms in a cyclic ether that forms the epoxy group are present on a saturated or unsaturated carbon ring having no aromaticity. Specifically, the alicyclic epoxy compound (A2) may include at least one compound selected from the group consisting of, for example, 3′,4′-epoxycyclohexylmethyl 3,4-epoxycyclohexane carboxylate, 3,4-epoxycyclohexylmethyl (3′,4′-epoxy) cyclohexane carboxylate, ¿-caprolactone-modified 3′,4′-epoxycyclohexylmethyl 3,4-epoxycyclohexane carboxylate, bis (3,4-epoxycyclohexyl) adipate, 1,2-epoxy-4-vinylcyclohexane, 1,4-cyclohexanedimethanol diglycidyl ether, epoxyethyl divinylcyclohexane, diepoxyvinylcyclohexane, 1,2,4-triepoxyethylcyclohexane, and limonene dioxide.

As long as the proportion by mass of the oxetane compound (A1) and the alicyclic epoxy compound (A2) to the total content of the cationic polymerizable component (A) is equal to or greater than 70% by mass, the cationic polymerizable component (A) may include any cationic polymerizable compound other than the oxetane compound (A1) and the alicyclic epoxy compound (A2).

The cationic polymerizable compound other than the oxetane compound (A1) and the alicyclic epoxy compound (A2) may include at least one compound selected from the group consisting of, for example, epoxy compounds (A3) other than the alicyclic epoxy compound (A2) and vinyl ether compounds. The epoxy compound (A3) preferably has photo-cationic polymerizability. However, this is only an example and should not be construed as limiting. Alternatively, the epoxy compound (A3) may have a thermally curing property.

Specifically, the epoxy compound (A3) may be at least one compound selected from the group consisting of, for example, biphenyl epoxy resins, bisphenol A epoxy resins, bisphenol F epoxy resins, bisphenol S epoxy resins, naphthalene ring-containing epoxy resins, anthracene ring-containing epoxy resins, phenol-novolac epoxy resins, cresol-novolac epoxy resins, triphenylmethane epoxy resins, brome-containing epoxy resins, and triglycidyl isocyanurate. The epoxy resin may have a glycidyl group.

Adding the epoxy compound (A3) to the cationic polymerizable component (A) makes it easier to control the rate of the curing reaction of the side-filling resin composition. If the cationic polymerizable component (A) includes the epoxy compound (A3), the proportion by mass of the epoxy compounds (A3) to the total content of the cationic polymerizable component (A) is greater than 0% by mass and less than 30% by mass.

The vinyl ether compound may be, for example, a compound having at least one vinyl ether skeleton in one molecule. Specifically, the vinyl ether compound may be at least one compound selected from the group consisting of, for example, ethylene glycol divinyl ether, diethylene glycol divinyl ether, triethylene glycol divinyl ether, polyethylene glycol divinyl ether, propylene glycol divinyl ether, butylene glycol divinyl ether, hexanediol divinyl ether, bisphenol A alkylene oxide divinyl ether, and bisphenol F alkylene oxide divinyl ether.

If the cationic polymerizable component (A) includes the vinyl ether compound, the proportion by mass of the vinyl ether compound to the total content of the cationic polymerizable component (A) is, for example, greater than 0% by mass and less than 30% by mass.

The cationic polymerizable component (A) does not have to be any one of the compounds described above but may also be a monomer or oligomer having appropriate cation polymerizability. In addition, the cationic polymerizable component (A) may include any resin other than the above-described ones.

The proportion by mass of the cationic polymerizable component (A) to the total solid content of the side-filling resin composition is preferably equal to or greater than 10% by mass and equal to or less than 60% by mass. This would impart an even higher degree of UV curability to the side-filling resin composition. Making the proportion by mass of the cationic polymerizable component (A) to the total solid content of the side-filling resin composition equal to or greater than 10% by mass makes it easier to maintain the viscosity more perfectly while the side-filling resin composition is being molded. Making the proportion by mass equal to or less than 60% by mass makes it easier to maintain the coefficient of thermal expansion of the cured product of the side-filling resin composition at a low value and also makes it even easier to further increase the thermal shock resistance of the semiconductor device 1 including this cured product. As used herein, the “total solid content” refers to the total content of components other than a vaporizable component such as a solvent. The proportion by mass of the cationic polymerizable component (A) to the total solid content of the side-filling resin composition is more preferably equal to or greater than 10% by mass and equal to or less than 50% by mass, and even more preferably equal to or greater than 10% by mass and equal to or less than 40% by mass.

### [Photo-Cationic Polymerization Initiator]

The side-filling resin composition according to this embodiment contains a photo-cationic polymerization initiator (B) included in the cationic polymerization initiator. The photo-cationic polymerization initiator (B) may promote the curing reaction of the cationic polymerizable component (A) in the side-filling resin composition. The photo-cationic polymerization initiator (B) preferably functions as a photoacid generator, for example. As used herein, the “photoacid generator” refers to a compound performing the function of polymerizing a polymerizable component. More specifically, when absorbing the light irradiating the photoacid generator, the photoacid generator is decomposed and generates an acid, thereby performing the function of polymerizing the polymerizable component.

The photo-cationic polymerization initiator (B) contributes to curing the side-filling resin composition by irradiating the side-filling resin composition with light, for example. In this embodiment, the side-filling resin composition has photocurability. This makes it even easier to remove the side-filling member 4 as a cured product of the side-filling resin composition in the semiconductor device 1.

The photo-cationic polymerization initiator (B) may be a polymerization initiator including an appropriate onium cation as a cationic species and an appropriate anionic species. Examples of the onium cations include sulfonium cations and iodonium cations. The anionic species include at least one anion selected from the group consisting of, for example, PF₆⁻, B(C₆F₅)₄⁻, SbF₆⁻, CF₃SO₃⁻, CF₃(CF₂)₃SO₃⁻, p-CH₃(CH₂)₁₀C₆H₄SO₃⁻, dinonylnaphthalene sulfonate anions, and p-toluenesulfonate anions.

The photo-cationic polymerization initiator (B) includes at least one compound selected from the group consisting of, for example, triarylsulfonium (Rf)ₙPF₆₋ₙ salts, triarylsulfonium PF₆ salts, triarylsulfonium SbF₆ salts, triarylsulfonium B(C₆F₅) salts, bis [4-n-alkyl (C10-C13) phenyl] iodonium hexafluoro phosphate, bis [4-n-alkyl (C10-C13) phenyl] iodonium hexafluoro antimonate, bis [4-n-alkyl (C10-C13) phenyl] iodonium tetrakis (pentafluorophenyl) borate, and bis (4-tert-butylphenyl)iodonium hexafluorophosphate.

The photo-cationic polymerization initiator (B) preferably generates an acid when irradiated with light having a wavelength equal to or longer than 200 nm and equal to or shorter than 400 nm, for example.

Examples of specific commercial products of the photo-cationic polymerization initiator (B) include sulfonium salts (triarylsulfonium salt types CPI-100P, CPI-101A, CPI-200K, CPI-210S, CPI-310B, and CPI-410S) and iodonium salts (such as IK-1) both manufactured by San-Apro Ltd. and WPI series of iodonium salts manufactured by Fujifilm Wako Pure Chemical Corporation (such as WPI-113, WPI-116, WPI-124, and WPI-170).

The proportion by mass of the photo-cationic polymerization initiator (B) to 100 parts by mass of the cationic polymerizable component (A) is preferably equal to or greater than 0.1 parts by mass and equal to or less than 10 parts by mass. This makes it even easier to improve the repairability of the cured product of the side-filling resin composition. The proportion by mass of the photo-cationic polymerization initiator (B) to 100 parts by mass of the cationic polymerizable component (A) is more preferably equal to or greater than 0.3 parts by mass and equal to or less than 8 parts by mass and even more preferably equal to or greater than 0.5 parts by mass and equal to or less than 5 parts by mass.

### [Inorganic Filler]

The side-filling resin composition preferably further contains an inorganic filler (C). Adding the inorganic filler (C) to the side-filling resin composition enables lowering the coefficient of thermal expansion (CTE) of a cured product of the side-filling resin composition. This reduces the chances of causing warpage to the side-filling member 4. This further reduces failures to be caused by generation of heat in the semiconductor device 1.

If the side-filling resin composition contains the inorganic filler (C), the proportion by mass of the inorganic filler (C) to the total solid content of the side-filling resin composition is preferably equal to or greater than 10% by mass and equal to or less than 90% by mass. This makes it easier to further lower the CTE of the cured product of the side-filling resin composition. The proportion by mass of the inorganic filler (C) to the total solid content of the side-filling resin composition is more preferably equal to or greater than 30% by mass and equal to or less than 90% by mass. Making the proportion by mass of the inorganic filler (C) to the total solid content of the side-filling resin composition equal to or greater than 30% by mass enables further lowering the CTE of the cured product of the side-filling resin composition and makes it easier to further improve the reliability in the heat resistance of the semiconductor device 1. Meanwhile, making this proportion equal to or less than 90% by mass allows the side-filling resin composition to be prepared as a liquid one as intended. The proportion by mass of the inorganic filler (C) to the total solid content of the side-filling resin composition is even more preferably equal to or greater than 50% by mass and equal to or less than 90% by mass.

The inorganic filler (C) contains at least one material selected from the group consisting of, for example, silica, alumina, clay, mica, talc, aluminum hydroxide, magnesium hydroxide, calcium carbonate, and glass. The silica may be, for example, molten silica, crystalline silica, or fumed silica.

If the inorganic filler (C) contains silica, then the silica may be subjected to surface treatment. Subjecting the silica to surface treatment makes the silica easily compatible with the cationic polymerizable component (A) in the side-filling resin composition, thus increasing the degree of dispersion of the side-filling resin composition. The silica may be subjected to surface treatment by treating the silica with a silane coupling agent, for example. The silane coupling agent may be, for example, a compound including at least one functional group selected from the group consisting of, for example, an epoxy group, an amino group, a (meth)acryloyl group, and a phenyl group.

The inorganic filler (C) preferably has a mean particle size equal to or greater than 2.5 μm and equal to or less than 200 μm, for example. Setting the mean particle size of the inorganic filler (C) within this range allows the side-filling resin composition, which is interposed between the base member 2 and the peripheral edge portion of the surface, facing the base member 2, of the mounted component 3, to maintain even better flowability. As used herein, the “mean particle size” refers to a volume-based median diameter D50. The median diameter D50 is calculated based on a particle size distribution obtained by measurement by the laser diffraction and scattering method. The particle size distribution may be measured with, for example, a laser diffraction particle size analyzer.

### [Other Components]

The side-filling resin composition may contain any additional components other than the above-described ones unless the advantages of the present disclosure are impaired. For example, the side-filling resin composition may contain additional resin components other than the resin components described above. The side-filling resin composition may contain a radical polymerizable compound, for example.

Optionally, the side-filling resin composition may contain any appropriate additive. Examples of the additives include a curing agent, a stabilizer, a photosensitizer, a flux, a viscosity modifier, a thixotropic agent, a surface conditioner, a silane coupling agent, an antifoaming agent, a leveling agent, a low stress agent, and a pigment. For example, the side-filling resin composition may contain a thixotropic agent. This makes it easier to allow, when supplying the side-filling resin composition to the gap between the base member 2 of the semiconductor device 1 and the peripheral edge portion of the surface, facing the base member 2, of the mounted component 3, the side-filling resin composition to maintain even better flowability and thixotropic property. This allows the side-filling resin composition to have even higher moldability. Consequently, this enables, even if the side-filling member 4 for reinforcing the peripheral edge portion of the mounted component 3 is formed out of the side-filling resin composition, imparting excellent strength to the side-filling member 4.

The side-filling resin composition may contain a stabilizer. Adding a stabilizer to the side-filling resin composition allows the side-filling resin composition to maintain good storage stability, even if the side-filling resin composition contains a cationic polymerization initiator. As the stabilizer, a stabilizer such as an appropriate antioxidant may be used. Examples of stabilizers include 2,6-tert-butyl-p-cresol, butylated hydroxy anisole, 2,6-tert-butyl-p-ethylphenol, 2,2-methylene bis (4-methyl-6-tert-butylphenol), 2,2-methylene bis (4-ethyl-6-tert-butylphenol), and 4,4′-thio bis (3-methyl-6-tert-butylphenol).

The side-filling resin composition may contain a softening agent. This would further improve the repairability when the semiconductor device 1 has some defective components that need repairing. Nevertheless, the side-filling resin composition according to this embodiment may still achieve a high degree of repairability as described above even if the side-filling resin composition contains no softening agent.

The side-filling resin composition may also contain a photosensitizer. This may promote the curing reaction of the side-filling resin composition. Consequently, this may shorten the takt time when forming a cured product out of the side-filling resin composition.

The side-filling resin composition preferably contains no organic solvent or has an organic solvent content equal to or less than 0.5% by mass. This makes it easier to maintain good viscosity when molding the side-filling resin composition.

The side-filling resin composition may be obtained by, for example, compounding the above-described components together with an appropriate additive added to the mixture as needed. Specifically, the side-filling resin composition may be prepared by the following method, for example.

First, the components that may be included in the side-filling resin composition described above are compounded together either simultaneously or sequentially to obtain a mixture. The mixture is stirred up and homogenized while being subjected to heating or cooling treatment as needed.

Next, an additive is added as needed to the mixture, which is stirred up again and further homogenized until the respective components are dispersed uniformly in the resultant mixture while being subjected to heating or cooling treatment as needed. In this manner, the side-filling resin composition may be obtained. To stir up the mixture, a disper, a planetary mixer, a ball mill, a three-roll, a bead mill, and/or any other suitable mixer may be used in an appropriate combination as needed.

The side-filling resin composition preferably has a viscosity equal to or greater than 10 Pa's and equal to or less than 2000 Pas at 25° C. This makes it easier to ensure sufficient moldability for the side-filling resin composition. In addition, in that case, sufficient fillability would be achieved between the base member 2 and the peripheral edge portion of the surface, facing the base member 2, of the mounted component 3 such as a semiconductor chip. The viscosity of the side-filling resin composition at 25° C. may be measured with a Type B viscosimeter under the condition including a rotor No. 7, the number of revolutions of 1 to 50 rpm, and a measuring time of 60 to 180 seconds. The condition for measuring the viscosity may be appropriately adjusted according to the composition of the resin composition, for example. The number of revolutions may be set at the maximum number of revolutions that can be measured with respect to the resin composition. The measuring time may be set at a time it takes for the rotor to make three or more rotations with respect to the resin composition. A specific measuring method will be described in detail later in the Examples section. The viscosity of the side-filling resin composition at 25° C. is more preferably equal to or less than 1000 Pa·s, even more preferably equal to or less than 700 Pa·s, and particularly preferably equal to or less than 400 Pa·s. The viscosity of the side-filling resin composition at 25° C. is more preferably equal to or greater than 50 Pa·s and even more preferably equal to or greater than 100 Pa·s.

The side-filling resin composition according to this embodiment has photocurability as described above. Thus, the side-filling resin composition may be cured when irradiated with light. The light irradiation condition, including the wavelength of the light radiated, the intensity of the light radiated (i.e., the quantity of the light radiated), and the duration of the light radiated, and the heating temperature and heating duration, may be adjusted appropriately according to the types of the components (such as the cationic polymerizable component (A)) that may be included in the side-filling resin composition and the type of the photo-cationic polymerization initiator (B). Any appropriate light source may be adopted as a light source for irradiating the side-filling resin composition with light. The light source may be at least one type of light source selected from the group consisting of, for example, a chemical lamp, a low-pressure mercury lamp, a medium-pressure mercury lamp, a high-pressure mercury lamp, an ultrahigh pressure mercury lamp, a xenon lamp, a metal halide lamp, an LED, a YAG, a g-line (with a wavelength of 436 nm), an h-line (with a wavelength of 405 nm), an i-line (with a wavelength of 365 nm), and combination of two or more types selected from the g-line, the h-line, and the i-line. However, the light source does not have to be one of these light sources but may also be any other light source that may irradiate, and thereby cure, the side-filling resin composition with an ultraviolet ray. The side-filling resin composition may be heated with an appropriate heater.

A cured product of the side-filling resin composition preferably has a glass transition temperature (Tg) equal to or higher than 130° C. Setting the glass transition temperature at a temperature equal to or higher than 130° C. allows the cured product of the side-filling resin composition to have heat resistance. The glass transition temperature may be measured by thermomechanical analysis (TMA), for example. In addition, setting the glass transition temperature at a temperature equal to or higher than 130° C. may reduce the chances of the cured product of the side-filling resin composition being softened even in a high-temperature range (of around 125ºC, for example) in a heat-cycle test. This allows the side-filling resin composition to ensure high reliability in heat resistance for the semiconductor device 1. Among other things, if the mounted component on the board is reinforced with a side-filling member made of a cured product of a known resin composition in the semiconductor device 1, exposing the semiconductor device 1 to a severe thermal environment (e.g., at a temperature of −40° C. or less or 125° C. or more) would often cause conduction failures between the board and the mounted component. In contrast, forming the side-filling member to reinforce the mounted component 3 on the base member 2 in the semiconductor device 1 out of the side-filling resin composition according to this embodiment allows the cured product of the side-filling resin composition to impart high thermal shock resistance to the semiconductor device 1. Thus, this embodiment may reduce the chances of causing conduction failures to the semiconductor device 1.

It is also preferable that the cured product of the side-filling resin composition have a coefficient of thermal expansion (CTE) less than 40 ppm/° ° C. at a temperature equal to or lower than the glass transition temperature Tg. This reduces not only the chances of causing warpage to the side-filling member 4 made of the cured product of the side-filling resin composition but also the chances of causing peeling of the cured product of the side-filling resin composition from the base member 2 and the mounted component 3 at a temperature equal to or lower than the glass transition temperature. Consequently, this reduces the chances of causing cracks in the cured product of the side-filling resin composition. Thus, the side-filling member 4 made of the side-filling resin composition may further improve the reliability in the heat resistance of the semiconductor device 1. The CTE of the cured product of the side-filling resin composition at a temperature equal to or lower than Tg is more preferably equal to or less than 35 ppm/° ° C. and is even more preferably equal to or less than 30 ppm/° C. or less. The CTE of the cured product of the side-filling resin composition at a temperature equal to or lower than Tg is obtained by calculating the gradient of a tangential line based on a variation in dimension between two arbitrary temperatures that are equal to or lower than Tg.

The side-filling resin composition according to this embodiment is preferably used as a side-filling member as described above. The side-filling resin composition may be used particularly preferably as a side-filling member to be supplied in a late stage of a flip-chip bonding process.

### [Semiconductor Device]

As described above, the side-filling resin composition according to this embodiment is preferably used to form the side-filling member 4 for reinforcing the base member 2 and the mounted component 3 in the semiconductor device 1. In particular, the side-filling resin composition may reinforce the base member 2 and the mounted component 3 just by supplying the side-filling resin composition to the gap between the base member 2 and the peripheral edge portion of the surface, facing the base member 2 of the mounted component 3. Thus, compared to the underfilling material to be supplied to fill the entire gap between the base member 2 and the mounted component 3, the amount of the resin composition to supply may be reduced. This makes the reinforced mounted component 3 hardly peelable unintentionally and reduces the chances of causing conduction failures to the semiconductor device 1.

In addition, to repair the semiconductor device 1 when a contact failure has occurred between the base member 2 and the mounted component 3 in the semiconductor device 1, only the side-filling member 4 that supports the base member 2 and the mounted component 3 (specifically, the side-filling member 4 interposed in the peripheral edge portion of the mounted component 3) needs to be peeled off. This allows the semiconductor device 1 to be repaired without discarding members that operate properly. In addition, the side-filling member 4 according to this embodiment is easily removable even without being heated to an excessively high temperature. Thus, the side-filling member 4 made of the side-filling resin composition according to this embodiment ensures excellent repairability for the semiconductor device 1. Furthermore, this reduces, when the semiconductor device 1 is repaired, the chances of discarding properly operating components other than defective components as described above, thus contributing to cutting down the cost in cases of failures, compared to the underfilling material.

A semiconductor device 1 according to this embodiment includes the base member 2, the mounted component 3, and the side-filling member 4. The mounted component 3 is surface-mounted on the base member 2. The side-filling member 4 is interposed between the base member 2 and the peripheral edge portion of the surface, facing the base member 2, of the mounted component 3. The side-filling member 4 is made of the cured product of the side-filling resin composition described above.

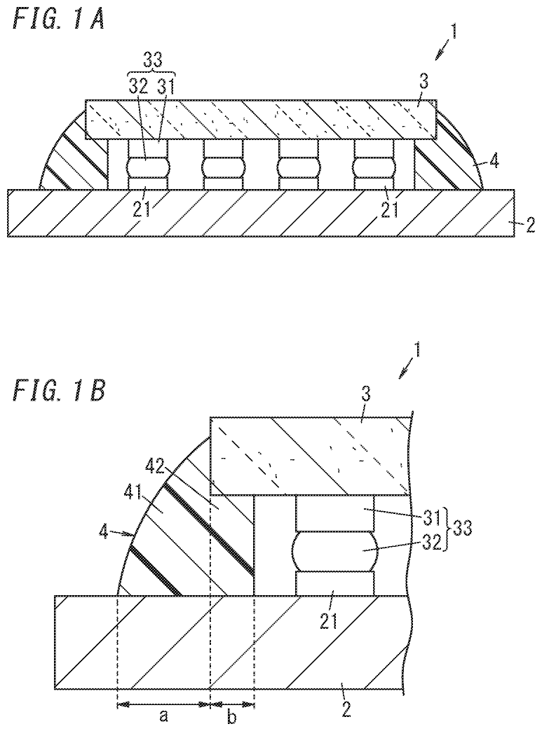

FIG. 1A illustrates an example of a semiconductor device 1 according to this embodiment.

The semiconductor device 1 includes: the base member 2 for supporting the mounted component 3 such as a semiconductor chip: the mounted component 3 that is surface-mounted face down on the base member 2; and the side-filling member 4 interposed between the base member 2 and the mounted component 3, more specifically, between the base member 2 and the peripheral edge portion of the surface, facing the base member 2, of the mounted component 3. The side-filling member 4 may support the base member 2 and the mounted component 3 in the gap between the base member 2 and the peripheral edge portion of the mounted component 3. That is to say, in the semiconductor device 1 shown in FIG. 1, the side-filling member 4 fills the gap between the base member 2 and the mounted component 3, more specifically, fills the gap only partially between the base member 2 and a part of the peripheral edge portion of the surface, facing the base member 2, of the mounted component 3. This allows the side-filling member 4 to reinforce the mounted component 3, which is surface-mounted on the base member 2, in the peripheral edge portion of the mounted component 3.

The side-filling member 4 is formed by supplying the side-filling resin composition to the base member 2 and a part or all of the peripheral edge portion of the surface, facing the base member 2, of the mounted component 3 between the base member 2 and the mounted component 3 and then photo-curing the side-filling resin composition thus supplied. The distance (infiltration distance) to which the side-filling resin composition is allowed to infiltrate inside the peripheral edge portion of the surface, facing the base member 2, of the mounted component 3 in plan view (i.e., to the gap left in the peripheral edge portion of the mounted component 3 between the base member 2 and the mounted component 3) may be appropriately adjusted. For example, as shown in FIG. 1B, the infiltration distance b is preferably equal or shorter than the distance a from a point, corresponding to the outer periphery of the mounted component 3, of the side-filling resin composition to an outer point outside of the surface, facing the base member 2, of the mounted component 3 (i.e., b≤a is preferably satisfied). As used herein, the “infiltration distance” refers to the length to which the side-filling resin composition has infiltrated inward, on the surface, facing the base member 2, of the mounted component 3, from the outer periphery of the mounted component 3 in plan view to some internal point on the surface, facing the base member 2, of the mounted component 3.

Next, a semiconductor device 1 and a method for fabricating the semiconductor device 1 according to this embodiment will be described in further detail.

The semiconductor device 1 includes: the base member 2 including conductor wiring 21: the mounted component 3 such as a semiconductor chip including bump electrodes 33 and mounted onto the base member 2 by having the bump electrodes 33 bonded onto the conductor wiring 21; and the side-filling member 4 (refer to FIG. 1A). The side-filling member 4 is a cured product of the side-filling resin composition described above.

The base member 2 may be a motherboard, a package board, or an interposer board, for example. In this embodiment, the base member 2 includes an insulating substrate made of glass epoxy, polyimide, polyester, a ceramic, or any other suitable material and the conductor wiring 21 made of an electrical conductor such as copper and formed on its surface. The conductor wiring 21 includes electrode pads, for example. Also, the side-filling resin composition according to this embodiment is effectively applicable to a printed wiring board. Thus, the base member 2 may be the substrate of an appropriate printed wiring board. Examples of substrates for the printed wiring board include organic resin substrates such as FR-4, ceramic substrates, metallic base substrates, and glass substrates.

The mounted component 3 may be a semiconductor chip, for example. The semiconductor chip may be a flip-chip bonded chip such as a ball-grid array (BGA), a land-grid array (LGA), or a chip size package (CSP) chip. Alternatively, the semiconductor chip may also be a package on package (POP) chip.

The mounted component 3 may include a plurality of bump electrodes 33. Each of the bump electrodes 33 includes solder. As shown in FIG. 1, each bump electrode 33 may include, for example, a pillar 31 and a solder bump 32 provided at the tip of the pillar 31. The solder bump 32 is made of solder, and therefore, each bump electrode 33 includes the solder. The pillar 31 may be made of copper, for example.

The melting point of the solder contained in each bump electrode 33 (e.g., the solder of the solder bump 32 thereof) is not limited to any particular value but may be set at any temperature as long as the solder may be melted at a temperature equal to or lower than the mounting temperature (of 220° C. to 260ºC, for example) when the mounted component 3 such as a semiconductor chip is mounted. Also, the composition of the solder is not limited to any particular one but may be an appropriate composition. The solder may be, for example, an Sn—Ag based solder or an Sn—Ag—Cu based solder. Note that the bump electrode 33 including solder does not have to have the structure described above but may include only a spherical solder bump 32 (solder ball), for example. That is to say, the bump electrode 33 does not have to include the pillar.

A method for fabricating the semiconductor device 1 according to this embodiment includes an application step and a curing step. The application step includes applying the side-filling resin composition onto the peripheral edge portion of the surface, facing the base member 2, of the mounted component 3. The curing step includes curing the side-filling resin composition that has been applied in the application step.

The application step preferably includes applying the side-filling resin composition to make the volume of the side-filling member 4 interposed between the base member 2 and the mounted component 3 in the peripheral edge portion of the surface, facing the base member 2, of the mounted component 3 is less than the volume of the side-filling member 4 applied only onto the base member 2. This enables shortening the takt time it takes to fabricate the semiconductor device 1 while increasing the reinforcement strength of the cured product of the side-filling resin composition between the base member 2 and the mounted component 3 in the semiconductor device 1. In addition, this also reduces the chances of applying stress to the solder bumps 32 and other members of the semiconductor device 1. This contributes to increasing the reliability of the semiconductor device 1 as well. Furthermore, even if the semiconductor device 1 comes to any defective components, the side-filling member 4 is easily removable, thus ensuring a particularly high degree of repairability.

The curing step includes irradiating the side-filling resin composition with light. To cure the side-filling resin composition, according to this embodiment, the side-filling resin composition is applied onto the peripheral edge portion of the mounted component 3, and then irradiated with light to cause the side-filling resin composition to be cured. In the curing step, light may be radiated from any appropriate light source, which is not limited to any particular one. That is to say, the light radiating condition and the light source may be the same as the above-described ones. In the example described above, the side-filling resin composition is cured by irradiating the side-filling resin composition with light. However, this is only an example and should not be construed as limiting. Alternatively, the side-filling resin composition may also be heated to be cured after having been irradiated with light without departing from the scope of the present disclosure.

In the semiconductor device 1 shown in FIG. 1A, the side-filling member 4 fills the gap only partially between the base member 2 and the mounted component 3, i.e., only the gap between the base member 2 and a part of the peripheral edge portion of the surface, facing the base member 2, of the mounted component 3. Specifically, the side-filling member 4 fills, in the peripheral edge portion of the surface, facing the base member 2, of the mounted component 3, the outside of the peripheral edge portion and a part of the inside of the peripheral edge portion. In the following description, the side-filling member that fills the outside of the peripheral edge portion will be hereinafter referred to as a “first side-filling member 41” and the side-filling member 4 that fills a part of the inside of the peripheral edge portion will be hereinafter referred to as a “second side-filling member 42.” FIG. 1B illustrates the first side-filling member 41 and the second side-filling member 42 only schematically and does not show the exact shapes and locations of the first side-filling member 41 and the second side-filling member 42.

This allows the side-filling member 4 to be interposed in the peripheral edge portion of the surface, facing the base member 2, of the mounted component 3 that is surface-mounted on the base member 2, thus reinforcing the base member 2 and the mounted component 3.

As for the side-filling member 4 for the semiconductor device 1, the volume of the side-filling member 4 present only on the base member 2 beside the peripheral edge portion of the surface, facing the base member 2, of the mounted component 3 (i.e., the volume of the first side-filling member 41) is preferably greater than the volume of the side-filling member 4 interposed in the gap between the base member 2 and the mounted component 3 (i.e., the volume of the second side-filling member 42). This reduces the chances of applying stress to the solder bumps 32 and other members of the semiconductor device 1, for example, thus contributing to increasing the reliability of the semiconductor device 1. In this embodiment, the side-filling resin composition has excellent UV curability. Thus, the first side-filling member 41 and the second side-filling member 42 may be formed by applying the side-filling resin composition onto appropriate areas and then irradiating the side-filling resin composition with light.

An exemplary method for fabricating the semiconductor device 1 will be described. Note that the method for fabricating the semiconductor device 1 to be described below is only an example and should not be construed as limiting. Rather, any other method may also be adopted as long as the method allows the semiconductor device 1 to be fabricated by forming the side-filling member 4 with the above-described side-filling resin composition supplied to cover part or all of the peripheral edge portion of the surface, facing the base member 2, of the mounted component 3 that is surface-mounted on the base member 2.

First, a base member 2 including conductor wiring 21 and a mounted component 3 including bump electrodes 33 are provided. The mounted component 3 is placed on the base member 2 and the bump electrodes 33 are arranged on the conductor wiring 21. The conductor wiring 21 and the bump electrodes 33 may be electrically connected together by heating, for example.

Subsequently, the side-filling resin composition is supplied onto the peripheral edge portion of the surface, facing the base member 2, of the mounted component 3 that is surface-mounted on the base member 2. Then, the side-filling resin composition thus supplied is irradiated with light, and thereby cured. In this manner, the side-filling member 4 is formed on the base member 2 and on the peripheral edge portion, facing the base member 2, of the mounted component 3. The condition for curing the side-filling resin composition is as described above.

These process steps do not have to be performed exactly in the above-described order. Rather, as long as the side-filling resin composition interposed may be placed during the manufacturing process to eventually cover the base member 2 and the peripheral edge portion of the surface, facing the base member 2, of the mounted component 3 either only partially or entirely, the side-filling resin composition may be placed at any timing during the manufacturing process anywhere on the mounted component 3 and the base member 2.

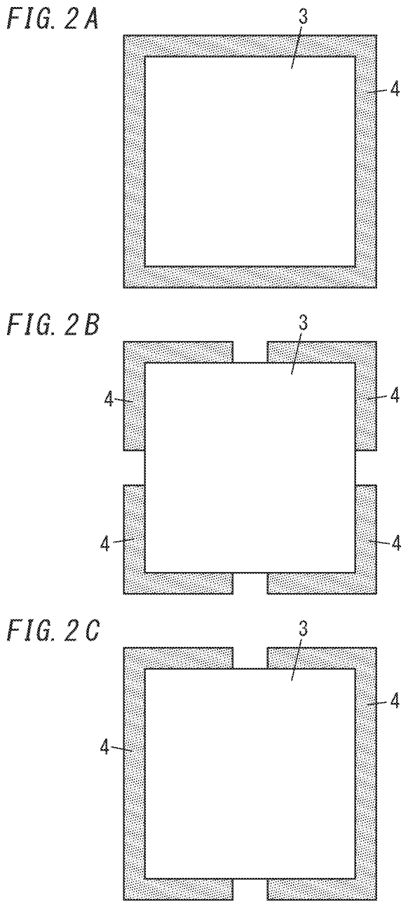

Specific exemplary regions where the side-filling member 4 may be placed in the semiconductor device 1 will be described with reference to FIGS. 2A-2C. Note that these are only exemplary regions where the side-filling member 4 may be placed in the semiconductor device 1.

In FIGS. 2A to 2C, the side-filling member 4 is formed in the semiconductor device 1 by supplying the side-filling resin composition to the gap between the base member 2 and the peripheral edge portion (in plan view) of the surface, facing the base member 2, of the mounted component 3 that is surface-mounted on the base member 2 and then curing the side-filling resin composition. That is to say, FIGS. 2A-2C illustrate three examples (hereinafter referred to as first, second, and third example, respectively) in which the base member 2 and the peripheral edge portion of the mounted component 3 are reinforced with the side-filling member 4. In the semiconductor devices 1 shown in FIGS. 2A-2C, the side-filling resin composition is not supplied to the depth of the gap between the base member 2 and the mounted component 3 (e.g., the entire lower surface, including the central area, of the mounted component 3) but supplied to only the peripheral edge portion of the surface, facing the base member 2, of the mounted component 3. The side-filling resin composition according to this embodiment is supplied to only the peripheral edge portion of the mounted component 3 but may still reinforce the base member 2 and the mounted component 3 of the semiconductor device 1. In particular, the side-filling member 4 made of the side-filling resin composition supports the peripheral edge portion of the mounted component 3 in the semiconductor device 1. That is to say, in this embodiment, the side-filling member 4 is not interposed in the entire gap between the base member 2 and the mounted component 3 but just supports the peripheral edge portion. This contributes to reducing the chances of the base member 2 and the mounted component 3 being warped.

In the first example illustrated in FIG. 2A, the side-filling member 4 made of a cured product of the side-filling resin composition is formed to cover the entire peripheral edges of the surface, facing the base member 2, of the mounted component 3. This increases the strength of the portion that reinforces the base member 2 and the mounted component 3 of the semiconductor device 1, thus further reducing the chances of causing warpage to the base member 2 and the mounted component 3. In addition, this also makes it easier, than in the case of the underfilling material, to repair the semiconductor device 1 when the semiconductor device 1 comes to have any defective components.

In the second example illustrated in FIG. 2B, the side-filling member 4 made of a cured product of the side-filling resin composition is formed to cover the base member 2 and a plurality of corner portions (more specifically, portions including the four corners of the mounted component 3 which is generally rectangular in plan view) in the peripheral edge portion of the surface, facing the base member 2, of the mounted component 3. This enables maintaining the strength of the portions that reinforce the base member 2 and the mounted component 3 of the semiconductor device 1, thus reducing the chances of causing warpage to the base member 2 and the mounted component 3. In addition, this also makes it easier, than in the case of the underfilling material, to repair the semiconductor device 1 when the semiconductor device 1 comes to have any defective components.

In the third example illustrated in FIG. 2C, the side-filling member made of a cured product of the side-filling resin composition is formed to cover the corner portions and two opposing sides of the surface, facing the base member 2, of the mounted component 3. This enables maintaining the strength of the portions that reinforce the base member 2 and the mounted component 3 of the semiconductor device 1, thus reducing the chances of causing warpage to the base member 2 and the mounted component 3. In addition, this also makes it easier, than in the case of the underfilling material, to repair the semiconductor device 1 when the semiconductor device 1 comes to have any defective components. Among other things, the side-filling member made of the side-filling resin composition according to this embodiment makes it easier to replace only defective parts when repair is made to eliminate the defects caused.

Next, a method for removing the side-filling member 4 from the semiconductor device 1 according to this embodiment will be described.

A method for removing the side-filling member according to this embodiment includes removing the side-filling member 4 from between the peripheral edge portion of the mounted component 3 and the base member 2 with the side-filling member 4 of the semiconductor device 1 heated to a temperature equal to or higher than 200° C. Repairing a defective part of the semiconductor device 1 requires melting the solder material such as the solder bumps 32 to electrically disconnect the base member 2 and the mounted component 3 from each other. According to this embodiment, the side-filling member 4 may be removed by heating the side-filling member 4 to a temperature equal to or higher than the melting temperature (of approximately 200° C.) of the solder material. Thus, the method for removing the side-filling member 4 according to this embodiment allows the semiconductor device 1 to be repaired easily.

### EXAMPLES

Next, specific examples of the present disclosure will be presented. Note that the following are only examples of the present disclosure and should not be construed as limiting.

### 1. Preparation of Side-Filling Resin Composition

### Examples 1-24 and Comparative Examples 1-5

The respective components shown in Tables 1-3 (to be posted at the end of this section) were compounded together at the respective ratios (parts by mass) shown in Tables 1-3, loaded into a planetary mixer, stirred up and mixed, and then uniformly dispersed with three rolls, thereby obtaining resin compositions. Following are the details of the components shown in Tables 1-3:

### (Polymerizable Components)

Cationic polymerizable components:
Oxetane compound 1: photo-cationic polymerizable compound (product name OXT-221 manufactured by Toagosei Co., Ltd.);
Oxetane compound 2: photo-cationic polymerizable compound (product name ETERNACOLL OXBP manufactured by UBE Corporation);
Alicyclic epoxy compound 1: photo-cationic polymerizable compound (product name Celloxide 2021 manufactured by Daicel Corporation);
Alicyclic epoxy compound 2: photo-cationic polymerizable compound (product name Celloxide 8000 manufactured by Daicel Corporation);
Alicyclic epoxy compound 3: photo-cationic polymerizable compound (product name Celloxide 2081 manufactured by Daicel Corporation); and
Another epoxy compound 1: product name EPICLON 840 manufactured DIC Corporation. (Photopolymerization initiator)
Cationic polymerization initiator 1: product name CPI-200K (photo-cationic polymerization initiator, 50% propylene carbonate solution of triarylsulfonium (Rf)ₙPF₆₋ₙ salt, where Rf is a perfluoroalkyl group), manufactured by San-Apro Ltd., non-antimony photoacid generator; and
Cationic polymerization initiator 2: product name: IRGACURE 290 (photo-cationic polymerization initiator, triarylsulfonium tetrakis-(pentafluorophenyl) borate), manufactured by BASF, non-antimony photoacid generator.

### (Thermal Curing Agent)

Thermal curing agent 1: acid anhydride curing agent (product name B650 manufactured by DIC Corporation); and
Thermal curing agent 2: imidazole-based curing agent (2MAOK manufactured by Shikoku Chemicals Corporation.)

### (Additives and Others)

Inorganic filler: product name QS-6 (30 μm cut) manufactured by MRC Unitec Co., Ltd.
Thixotropic agent: product name RY200 manufactured by Nippon Aerosil Co., Ltd.
Softening agent: product name LBR-302 manufactured by Kuraray Co., Ltd.

### 2. Evaluation Tests

### 2.1. Glass Transition Temperature

In Examples 1-24 and Comparative Examples 1 and 2, the side-filling resin composition prepared as described in the item 1. was applied onto a base member and had the upper surface of its base member (i.e., the surface on which the side-filling resin composition was applied) irradiated with light for 4 seconds by an LED UV irradiator (model number Aicure UD40 manufactured by Panasonic Industrial Device SUNX Co., Ltd.) under the condition including an illuminance of 1000 mW/cm². Subsequently, the base member and the side-filling resin composition that had been applied onto the base member and had been photocured were loaded into a heating furnace and heated at 100° ° C. for 30 minutes to be cured.

In Comparative Examples 3-5, the side-filling resin composition prepared as described in the item 1. was applied onto the base member and the base member and the side-filling resin composition that had been applied onto the base member were loaded into a heating furnace and heated at 150ºC for 30 minutes to be cured.

Each of the cured products of the side-filling resin composition thus obtained as the respective examples and comparative examples (hereinafter referred to as “respective examples and other examples”) was cut into multiple test pieces each having a width of 5 mm, a length of 50 mm, and a thickness of 0.2 mm.

Each of these test pieces thus obtained was subjected to measurement in a bending mode using a viscoelasticity spectrometer (model number DMA7100 manufactured by Hitachi High-Tech Corporation) and its glass transition temperature was calculated by the DMA method. The measuring condition included a frequency of 10 Hz, a temperature increase rate of 5° C./min, and a measuring temperature of −60° C. to 280° ° C. The glass transition temperatures (C) of the cured products thus obtained are shown in Tables 1-3.

### 2.2. Coefficient of Thermal Expansion (a1)

In each of the respective examples and other examples, the side-filling resin composition was cured under the same light irradiation condition and/or the same heating condition as the one described for the item 2.1. to obtain a cured product of the side-filling resin composition. The cured product of the side-filling resin composition thus obtained in each of the respective examples and other examples was cut into multiple test pieces, each having a width of 3 mm, a length of 3 mm, and a thickness of 15 mm.

Each of these test pieces was heated by the TMA method using a thermal analysis instrument (model number TMA7100 manufactured by Hitachi High-Tech Corporation) under the condition including a temperature increase rate of 5° C./min and a measuring temperature of 30 to 260° C., thereby calculating the coefficient of thermal expansion α1 at a temperature lower than Tg falling within a temperature range from 50° C. to 70° C. The coefficient of thermal expansion α1) (ppm/° C. of the cured product thus obtained is shown in Tables 1-3.

### 2.3. Viscosity

The side-filling resin composition that had been formed as described in the item 1 was loaded into a circular cylindrical container to have its viscosity value measured using a Type B viscometer (model number TVB10 manufactured by Toki Sangyo Co., Ltd.) under the condition including a rotor No. 7 and a measuring temperature of 25° C. The number of revolutions of the viscometer was set at the largest measurable number of revolutions falling within the range from 1 rpm to 50 rpm. The measuring duration was the time it took for the rotor to make three or more rotations and fell within the range from 60 seconds to 180 seconds. Specifically, in Examples 1-13, 15, 16, and 18-24 and Comparative Examples 1-4, the number of revolutions was set at 10 rpm and the measuring duration was set at 60 seconds. In Comparative Example 5, the number of revolutions was set at 5 rpm and the measuring duration was set at 60 seconds. In Example 14, the number of revolutions was set at 2.5 rpm and the measuring duration was set at 90 seconds. In Example 17, the number of revolutions was set at 1 rpm and the measuring duration was set at 180 seconds. The results thus obtained are summarized in Tables 1-3.

### 2.4. UV Curability

In each of the respective examples and other examples, 10 mg of the side-filling resin composition that had been prepared in the item 1. described above was harvested into an aluminum pan (q: 5 mm) for a differential scanning calorimetry (DSC). The side-filling resin composition thus harvested was irradiated with light having a wavelength of 365 nm and emitted from a UV light source (model number LA-410UV manufactured by HAYASHI-REPIC Co., Ltd.) at an irradiation intensity of 400 mW/cm² for 2 minutes. The heat of reaction (x1) generated by the photo-curing reaction during the irradiation was measured and calculated using a DSC measuring device manufactured by Hitachi High-Tech Corporation.

Subsequently, DSC measurement was carried out, under the condition including a temperature range of 0° ° C. to 260° C. and a temperature increase rate of 10° C./min, on the cured product that had been irradiated with the light as described above, thereby calculating the residual heat (x2) of the cured product.

Based on the heat of reaction (x1) and the residual heat (x2) thus obtained, the curing rate (R) was calculated by the following equation. The side-filling resin composition was evaluated as follows by the curing rate (R):

Curing rate (R[%])=[1−(x2)/((x1)+(x2))]×100
Grade A: if the curing rate was equal to or higher than 80%;
Grade B: if the curing rate was equal to or higher than 60% but lower than 80%, or
Grade C: if the curing rate was lower than 60%.

### 2.5. Repairability

On a glass epoxy substrate that had been subjected to solder resist treatment (base member: FR4 having a thickness of 0.6 mm and manufactured by Panasonic Corporation, and resist: PSR4000 manufactured by Taiyo Ink Mfg. Co., Ltd.), 10 mg of the side-filling resin composition formed as described in the item 1. was applied and cured, thereby forming a test piece including a cured product of the side-filling resin composition on the substrate. The curing condition was the same as the light irradiation condition or the heating condition described for the item 2.1.

Each of these test pieces was placed on a hotplate and heated for 10 minutes such that the substrate had a surface temperature of 200° C. After that, the operation of peeling the cured product off the substrate was performed using a bamboo skewer. Then, the conditions of the cured product and the substrate were inspected with the naked eye, thereby evaluating each test piece as one of the following three grades. The results are also summarized in Tables 1-3:
Grade A: if the cured product could be peeled off the substrate with no residues of the cured product left on the substrate;
Grade B: if the cured product could be peeled off the substrate but some residues of the cured product were left on the substrate; or
Grade C: if the cured product could not be peeled off the substrate and left on the substrate.

### 2.6. Temperature Cycle (TC) Characteristics

A test element group (TEG) was formed by mounting an IC chip for mounting (WLP TEG<BGA with a pitch of 0.3 mm>, 6 mm, manufactured by WALTS Co., Ltd.) on an FR-4 circuit board (WALTS KIT WLP 300P manufactured by WALTS Co., Ltd.) having a daisy chain electrode. The side-filling resin composition that had been formed as described in the item 1 was applied to have the planar shape shown in FIG. 2B (to form an L shape at each of the four corners) and a width of 0.8 mm and a height of 0.4 mm between the board and the peripheral edge portion of the surface, facing the board, of the IC chip in the TEG. The contact portion between the side-filling resin composition and the IC chip had a length of 2.5 mm. A test piece including a cured product of the side-filling resin composition was formed on the TEG by irradiating the side-filling resin composition applied with light and then heating the side-filling resin composition in a heating furnace. The curing condition was the same as the light irradiation condition or heating condition as described in the item 2.1.

Each test piece thus formed was subjected to a heat cycle test using a thermal shock tester (model number TSE-12-A manufactured by ESPEC Corporation). The heat cycle test was carried out in a gas phase such that each test piece was exposed, in each cycle, to a temperature of −40ºC for 30 minutes and a temperature of 125ºC for 30 minutes. This thermal shock test was performed in 2000 cycles in total. The operation of the test piece was checked by measuring the resistance value of the test piece every 100 cycles. A test piece, of which the resistance increased by 5% or more since the beginning of the test, was determined to be malfunctioning. Each test piece was evaluated as one of the following three grades. The results are also summarized in Tables 1-3:
Grade A: if the test piece did not malfunction even after having gone through more than 2000 cycles:
Grade B: if the test piece started to malfunction when the test piece went through the temperature cycles, of which the number was equal to or larger than 500 and equal to or less than 2000: or
Grade C: if the test piece started to malfunction when the test piece went through less than 500 cycles.

### 2.7. Discharge Performance

A syringe (product number PSY-10EU-OR) manufactured by Musashi Engineering Inc. was filled with the resin composition that had been prepared as described in the item 1. A needle (product number SNA-22G-B) manufactured by Musashi Engineering Inc. was attached to the tip of the syringe.

Subsequently, a dispensing robot (model number SHOTMASTER 300ΩX) manufactured by Musashi Engineering Inc. was made to apply the resin composition onto a glass plate through the syringe filled with the resin composition. The application step was performed such that the distance between the glass plate and the tip of the needle was 0.5 mm, the moving velocity was 3 mm/s, and the resin composition was applied linearly to a length of 10 cm. The appearance of the resin thus applied was subjected to a visual inspection to evaluate the resin as one of the following grades:
Grade A: if the resin composition could be applied without discontinuing on the way:
Grade B: if the resin composition could be applied but sometimes discontinued on the way; or
Grade C: if the resin composition could not be discharged from the needle.

### 2.8. Pot Life (Storage Stability of Resin Composition Solution)

First, the viscosity was measured in the same way as described in the item 2.3. Specifically, the side-filling resin composition that had been formed as described in the item 1 was loaded into a circular cylindrical container to have its viscosity value measured using a Type B viscometer (model number TVB10 manufactured by Toki Sangyo Co., Ltd.) under the condition including a rotor No. 7 and a measuring temperature of 25° C. The number of revolutions of the viscometer was set at the largest measurable number of revolutions falling within the range from 1 rpm to 50 rpm. The measuring duration was the time it took for the rotor to make three or more rotations and fell within the range from 60 seconds to 180 seconds. Specifically, in Examples 1-13, 15, 16, and 18-24 and Comparative Examples 1-4, the number of revolutions was set at 10 rpm and the measuring duration was set at 60 seconds. In Comparative Example 5, the number of revolutions was set at 5 rpm and the measuring duration was set at 60 seconds. In Example 14, the number of revolutions was set at 2.5 rpm and the measuring duration was set at 90 seconds. In Example 17, the number of revolutions was set at 1 rpm and the measuring duration was set at 180 seconds. These values were regarded as the viscosities right after the side-filling resin composition had been formed (hereinafter referred to as “initial viscosities”). Next, respective viscosity values of the side-filling resin composition were measured under the same condition when 24 hours, 48 hours, and 72 hours passed since the side-filling resin composition had been formed. Based on the initial viscosity values and the respective viscosity values measured when these amounts of time passed, the side-filling resin composition was evaluated by its pot life (storage stability) as one of the following grades:
Grade A: if the viscosity of the side-filling resin composition was still less than 1.5 times of the initial viscosity, even when 72 hours passed since the resin composition had been formed;
Grade B: if the viscosity of the side-filling resin composition was still less than 1.5 times of the initial viscosity when 48 hours passed since the resin composition had been formed, but became at least 1.5 times as high as the initial viscosity when 72 hours passed since then;
Grade C: if the viscosity of the side-filling resin composition was still less than 1.5 times of the initial viscosity when 24 hours passed since the resin composition had been formed, but became at least 1.5 times as high as the initial viscosity when 48 hours passed since then; or
Grade D: if the viscosity of the side-filling resin composition became at least 1.5 times as high as the initial viscosity when 24 hours passed since the resin composition had been formed.

TABLE 1

| | | | | Examples | | | | |
|---|---|---|---|---|---|---|---|---|
| | | | | 1 | 2 | 3 | 4 | 5 |
| Composition | Polymerizable | Cationic- | Oxetane compound 1 | 13.0 | 16.7 | 12.0 | — | 13.0 |
| (parts | component | polymerizable | Oxetane compound 2 | — | — | — | 13.0 | — |
| by mass) | | component | Alicyclic epoxy | 9.0 | 11.1 | 8.0 | 9.0 | — |
| | | | compound 1 | | | | | |
| | | | Alicyclic epoxy | — | — | — | — | 9.0 |
| | | | compound 2 | | | | | |
| | | | Alicyclic epoxy | — | — | — | — | — |
| | | | compound 3 | | | | | |
| | | | Another epoxy | 6.0 | 3.3 | 3.0 | 6.0 | 6.0 |
| | | | compound 1 | | | | | |

| | | | | | | |
|---|---|---|---|---|---|---|
| | Proportion by mass of oxetane | 78.6% | 89.4% | 87.0% | 78.6% | 78.6% |
| | compound and alicyclic epoxy | | | | | |
| | compound to total content of | | | | | |
| | polymerizable component | | | | | |
| Photopolymerization | Cationic polymerization initiator 1 | 1.0 | 1.1 | 1.0 | 1.0 | 1.0 |
| initiator | Cationic polymerization initiator 2 | — | — | — | — | — |
| | Proportion by mass of oxetane | 3.57% | 3.54% | 4.35% | 3.57% | 3.57% |
| | compound and alicyclic epoxy | | | | | |
| | compound to total content of | | | | | |
| | polymerizable component | | | | | |
| Thermal curing | Thermal curing agent 1 | — | — | — | — | — |
| agent | Thermal curing agent 2 | — | — | — | — | — |

| | | | | | | |
|---|---|---|---|---|---|---|
| | Inorganic filler | 70.0 | 66.7 | 75.0 | 70.0 | 70.0 |
| | Thixotropic agent | 1.0 | 1.1 | 1.0 | 1.0 | 1.0 |
| | Softening agent | — | — | — | — | — |
| | Total | 100.0 | 100.0 | 100.0 | 100.0 | 100.0 |
| Evaluation | Glass transition temperature (Tg) [° C.] | 140 | 150 | 140 | 135 | 160 |
| | Coefficient of thermal expansion (α1) [ppm/° C.] | 32 | 34 | 30 | 32 | 30 |
| | Viscosity [Pa · s] | 130 | 105 | 145 | 230 | 90 |
| | UV curability | A | A | A | A | A |
| | Repairability | A | A | A | A | A |
| | Temperature cycle (TC) characteristics | A | A | A | A | A |
| | Discharge performance | A | A | A | A | A |
| | Pot life | A | A | A | A | A |

| | | | | Examples | | | |
|---|---|---|---|---|---|---|---|
| | | | | 6 | 7 | 8 | 9 |
| Composition | Polymerizable | Cationic- | Oxetane compound 1 | 13.0 | 13.1 | 13.0 | 16.0 |
| (parts | component | polymerizable | Oxetane compound 2 | — | — | — | — |
| by mass) | | component | Alicyclic epoxy | 9.0 | 9.1 | 9.0 | 12.0 |
| | | | compound 1 | | | | |
| | | | Alicyclic epoxy | — | — | — | — |
| | | | compound 2 | | | | |
| | | | Alicyclic epoxy | — | — | — | — |
| | | | compound 3 | | | | |
| | | | Another epoxy | 6.0 | 6.0 | 6.0 | — |
| | | | compound 1 | | | | |

| | | | | | |
|---|---|---|---|---|---|
| | Proportion by mass of oxetane | 78.6% | 78.7% | 78.6% | 100% |
| | compound and alicyclic epoxy | | | | |
| | compound to total content of | | | | |
| | polymerizable component | | | | |
| Photopolymerization | Cationic polymerization initiator 1 | — | 0.3 | 1.4 | 1.0 |
| initiator | Cationic polymerization initiator 2 | 1.0 | — | — | — |
| | Proportion by mass of oxetane | 3.57% | 1.06% | 5.00% | 3.57% |
| | compound and alicyclic epoxy | | | | |
| | compound to total content of | | | | |
| | polymerizable component | | | | |
| Thermal curing | Thermal curing agent 1 | — | — | — | — |
| agent | Thermal curing agent 2 | — | — | — | — |

| | | | | | |
|---|---|---|---|---|---|
| | Inorganic filler | 70.0 | 70.5 | 69.5 | 70.0 |
| | Thixotropic agent | 1.0 | 1.0 | 1.0 | 1.0 |
| | Softening agent | — | — | — | — |
| | Total | 100.0 | 100.0 | 100.0 | 100.0 |
| Evaluation | Glass transition temperature (Tg) [° C.] | 140 | 140 | 140 | 160 |
| | Coefficient of thermal expansion (α1) [ppm/° C.] | 32 | 32 | 32 | 32 |
| | Viscosity [Pa · s] | 130 | 130 | 130 | 80 |
| | UV curability | A | A | A | A |
| | Repairability | A | A | A | A |
| | Temperature cycle (TC) characteristics | A | A | A | A |
| | Discharge performance | A | A | A | A |
| | Pot life | A | A | A | A |

TABLE 2

| | | | | Examples | | | | |
|---|---|---|---|---|---|---|---|---|
| | | | | 10 | 11 | 12 | 13 | 14 |
| Composition | Polymerizable | Cationic- | Oxetane compound 1 | 20.0 | | 10.0 | 16.8 | 6.0 |
| (parts | component | polymerizable | Oxetane compound 2 | — | — | — | — | — |
| by mass) | | component | Alicyclic epoxy | | 20.0 | 10.0 | 12.0 | 5.0 |
| | | | compound 1 | | | | | |
| | | | Alicyclic epoxy | — | — | — | — | — |
| | | | compound 2 | | | | | |
| | | | Alicyclic epoxy | — | — | — | — | — |
| | | | compound 3 | | | | | |
| | | | Another epoxy | 8.0 | 8.0 | 8.0 | 9.0 | 3.0 |
| | | | compound 1 | | | | | |

| | | | | | | |
|---|---|---|---|---|---|---|
| | Proportion by mass of oxetane | 71.4% | 71.4% | 71.4% | 76.2% | 78.6% |
| | compound and alicyclic epoxy | | | | | |
| | compound to total content of | | | | | |
| | polymerizable component | | | | | |
| Photopolymerization | Cationic polymerization initiator 1 | 1.0 | 1.0 | 1.0 | 1.4 | 0.5 |
| Initiator | Cationic polymerization initiator 2 | — | — | — | — | — |
| | Proportion by mass of oxetane | 3.57% | 3.57% | 3.57% | 3.70% | 3.57% |
| | compound and alicyclic epoxy | | | | | |
| | compound to total content of | | | | | |
| | polymerizable component | | | | | |
| Thermal curing | Thermal curing agent 1 | — | — | — | — | — |
| agent | Thermal curing agent 2 | — | — | — | — | — |

| | | | | | | |
|---|---|---|---|---|---|---|
| | Inorganic filler | 70.0 | 70.0 | 70.0 | 59.8 | 84.5 |
| | Thixotropic agent | 1.0 | 1.0 | 1.0 | 1.0 | 1.0 |
| | Softening agent | — | — | — | — | — |
| | Total | 100.0 | 100.0 | 100.0 | 100.0 | 100.0 |
| Evaluation | Glass transition temperature (Tg) [° C.] | 130 | 160 | 140 | 160 | 140 |
| | Coefficient of thermal expansion (α1) [ppm/° C.] | 32 | 32 | 32 | 36 | 24 |
| | Viscosity [Pa · s] | 85 | 190 | 140 | 65 | 840 |
| | UV curability | A | A | A | A | A |
| | Repairability | A | A | A | A | A |
| | Temperature cycle (TC) characteristics | A | A | A | A | A |
| | Discharge performance | A | A | A | A | A |
| | Pot life | A | A | A | A | A |

| | | | | Examples | | | |
|---|---|---|---|---|---|---|---|
| | | | | 15 | 16 | 17 | 18 |
| Composition | Polymerizable | Cationic- | Oxetane compound 1 | 31.1 | 40.0 | 3.7 | 13.1 |
| (parts | component | polymerizable | Oxetane compound 2 | — | — | — | — |
| by mass) | | component | Alicyclic epoxy | 21.6 | 27.7 | 2.6 | 9.1 |
| | | | compound 1 | | | | |
| | | | Alicyclic epoxy | — | — | — | — |
| | | | compound 2 | | | | |
| | | | Alicyclic epoxy | — | — | — | — |
| | | | compound 3 | | | | |
| | | | Another epoxy | 14.4 | 18.5 | 1.7 | 6.1 |
| | | | compound 1 | | | | |

| | | | | | |
|---|---|---|---|---|---|
| | Proportion by mass of oxetane | 78.5% | 78.5% | 78.8% | 78.4% |
| | compound and alicyclic epoxy | | | | |
| | compound to total content of | | | | |
| | polymerizable component | | | | |
| Photopolymerization | Cationic polymerization initiator 1 | 2.4 | 3.1 | 0.3 | 0.05 |
| Initiator | Cationic polymerization initiator 2 | — | — | — | — |
| | Proportion by mass of oxetane | 3.58% | 3.60% | 3.75% | 0.18% |
| | compound and alicyclic epoxy | | | | |
| | compound to total content of | | | | |
| | polymerizable component | | | | |
| Thermal curing | Thermal curing agent 1 | — | — | — | — |
| agent | Thermal curing agent 2 | — | — | — | — |

| | | | | | |
|---|---|---|---|---|---|
| | Inorganic filler | 29.5 | 9.7 | 90.7 | 70.6 |
| | Thixotropic agent | 1.0 | 1.0 | 1.0 | 1.0 |
| | Softening agent | — | — | — | — |
| | Total | 100.0 | 100.0 | 100.0 | 100.0 |
| Evaluation | Glass transition temperature (Tg) [° C.] | 140 | 140 | 140 | 140 |
| | Coefficient of thermal expansion (α1) [ppm/° C.] | 50 | 65 | 15 | 32 |
| | Viscosity [Pa · s] | 18 | 8 | 1920 | 130 |
| | UV curability | A | A | A | A |
| | Repairability | A | A | A | A |
| | Temperature cycle (TC) characteristics | A | B | A | A |
| | Discharge performance | A | A | B | A |
| | Pot life | A | A | A | A |

TABLE 3

| | | | | Examples | | | | |
|---|---|---|---|---|---|---|---|---|
| | | | | 19 | 20 | 21 | 22 | 23 |
| Composition | Polymerizable | Cationic- | Oxetane compound 1 | 12.8 | 13.1 | 12.7 | 12.7 | 13.3 |
| (parts | component | Polymerizable | Oxetane compound 2 | | | | | |
| by mass) | | Component | Alicyclic epoxy compound 1 | 8.9 | 9.1 | 8.8 | 8.8 | 9.3 |
| | | | Alicyclic epoxy compound 2 | | | | | |
| | | | Alicyclic epoxy compound 3 | | | | | |
| | | | Another epoxy compound 1 | 5.9 | 6.1 | 5.8 | 5.8 | 6.4 |

| | | | | | | |
|---|---|---|---|---|---|---|
| | Proportion by mass of oxetane compound | 78.6% | 78.4% | 78.8% | 78.8% | 77.9% |
| | and alicyclic epoxy compound to | | | | | |
| | total content of polymerizable component | | | | | |
| Photopolymerization | Cationic polymerization initiator 1 | 2.3 | 0.02 | 3.4 | 2.6 | 0.16 |
| initiator | Cationic polymerization initiator 2 | | | | | |
| | Proportion by mass of oxetane compound | 8.33% | 0.07% | 12.45% | 9.52% | 0.55% |
| | and alicyclic epoxy compound to | | | | | |
| | total content of polymerizable component | | | | | |
| Thermal curing | Thermal curing agent 1 | | | | | |
| agent | Thermal curing agent 2 | | | | | |

| | | | | | | |
|---|---|---|---|---|---|---|
| | Inorganic filler | 69.0 | 70.7 | 68.2 | 69.0 | 69.8 |
| | Thixotropic agent | 1.0 | 1.0 | 1.0 | 1.0 | 1.0 |
| | Softening agent | | | | | |
| | Total | 100.0 | 100.0 | 100.0 | 100.0 | 100.0 |
| Evaluation | Glass transition temperature (Tg) [° C.] | 140 | 140 | 140 | 140 | 140 |
| | Coefficient of thermal expansion (α1) [ppm/° C.] | 32 | 32 | 32 | 32 | 32 |
| | Viscosity [Pa · s] | 130 | 130 | 130 | 130 | 130 |
| | UV curability | A | B | A | A | A |
| | Repairability | A | A | A | A | A |
| | Temperature cycle (TC) characteristics | A | B | A | A | A |
| | Discharge performance | A | A | A | A | A |
| | Pot life | A | A | B | A | A |

| | | | | Examples | Comparative Examples | | | | |
|---|---|---|---|---|---|---|---|---|---|
| | | | | 24 | 1 | 2 | 3 | 4 | 5 |
| Composition | Polymerizable | Cationic- | Oxetane compound 1 | 13.0 | 7.0 | 9.0 | | | |
| (parts | component | Polymerizable | Oxetane compound 2 | | | | | | |
| by mass) | | Component | Alicyclic epoxy compound 1 | | 6.0 | 9.0 | 7.0 | | |
| | | | Alicyclic epoxy compound 2 | | | | | | |
| | | | Alicyclic epoxy compound 3 | 9.0 | | | | | |
| | | | Another epoxy compound 1 | 6.0 | 15.0 | 10.0 | 7.5 | 36.0 | 32.0 |

| | | | | | | | |
|---|---|---|---|---|---|---|---|
| | Proportion by mass of oxetane compound | 78.6% | 46.4% | 64.3% | 48.3% | 0% | 0% |
| | and alicyclic epoxy compound to | | | | | | |
| | total content of polymerizable component | | | | | | |
| Photopolymerization | Cationic polymerization initiator 1 | 1.0 | 1.0 | 1.0 | | | |
| initiator | Cationic polymerization initiator 2 | — | | | | | |
| | Proportion by mass of oxetane compound | 3.57% | 3.57% | 3.57% | 0% | 0% | 0% |
| | and alicyclic epoxy compound to | | | | | | |
| | total content of polymerizable component | | | | | | |
| Thermal curing | Thermal curing agent 1 | | | | 13.5 | | |
| agent | Thermal curing agent 2 | | | | 1.0 | 2.0 | 2.0 |

| | | | | | | | |
|---|---|---|---|---|---|---|---|
| | Inorganic filler | 70.0 | 70.0 | 70.0 | 70.0 | 60.0 | 60.0 |
| | Thixotropic agent | 1.0 | 1.0 | 1.0 | 1.0 | 2.0 | 4.0 |
| | Softening agent | | | | | | 2.0 |
| | Total | 100.0 | 100.0 | 100.0 | 100.0 | 100.0 | 100.0 |
| Evaluation | Glass transition temperature (Tg) [° C.] | 130 | 130 | 140 | 160 | 160 | 100 |
| | Coefficient of thermal expansion (α1) [ppm/° C.] | 33 | 32 | 32 | 32 | 36 | 36 |
| | Viscosity [Pa · s] | 210 | 290 | 230 | 180 | 250 | 480 |
| | UV curability | A | C | C | C | C | C |
| | Repairability | A | A | A | C | C | B |
| | Temperature cycle (TC) characteristics | A | B | B | A | A | C |
| | Discharge performance | A | A | A | A | A | A |
| | Pot life | A | A | A | C | B | B |

### REFERENCE SIGNS LIST

1 Semiconductor Device
2 Base Member
3 Mounted Component
4 Side-Filling Member

1. A side-filling resin composition for use to form a side-filling member to be interposed between a base member and a peripheral edge portion of a surface, facing the base member, of a mounted component that is surface-mounted on the base member,
the side-filling resin composition containing a cationic polymerizable component (A) and a photo-cationic polymerization initiator (B),
the cationic polymerizable component (A) including at least one compound selected from the group consisting of an oxetane compound (A1) and an alicyclic epoxy compound (A2), and
proportion by mass of the oxetane compound (A1) and the alicyclic epoxy compound (A2) to a total content of the cationic polymerizable component (A) being equal to or greater than 70% by mass.

2. The side-filling resin composition of claim 1, wherein
proportion by mass of the photo-cationic polymerization initiator (B) to the total content of the cationic polymerizable component (A) is equal to or greater than 0.1% by mass and equal to or less than 10% by mass.

3. The side-filling resin composition of claim 1, further containing an inorganic filler (C).

4. The side-filling resin composition of claim 3, wherein
proportion by mass of the inorganic filler (C) to a total content of the side-filling resin composition is equal to or greater than 10% by mass and equal to or less than 90% by mass.

5. The side-filling resin composition of claim 1, wherein
the cationic polymerizable component (A) includes both the oxetane compound (A1) and the alicyclic epoxy compound (A2).

6. The side-filling resin composition of claim 1, further containing an epoxy compound (A3) other than the alicyclic epoxy compound (A2), wherein
proportion by mass of the epoxy compound (A3) to the total content of the cationic polymerizable component (A) is greater than 0% by mass and less than 30% by mass.

7. The side-filling resin composition of claim 1, wherein
the side-filling resin composition has a viscosity equal to or greater than 10 Pa·s and equal to or less than 2000 Pa·s at 25° C.

8. A semiconductor device comprising: a base member; a mounted component that is surface-mounted on the base member; and a side-filling member interposed between the base member and a peripheral edge portion of a surface, facing the base member, of the mounted component,
the side-filling member being made of a cured product of the side-filling resin composition of claim 1.

9. A method for removing a side-filling member, the method comprising removing the side-filling member of the semiconductor device of claim 8 from between a peripheral edge portion of the mounted component and the base member while heating the side-filling member to a temperature equal to or higher than 200° C.

10. A method for fabricating a semiconductor device, the semiconductor device including: a base member; a mounted component that is surface-mounted on the base member; and a side-filling member interposed between the base member and a peripheral edge portion of a surface, facing the base member, of the mounted component,
the side-filling member being made of a cured product of the side-filling resin composition of claim 1;
the method comprising:
an application step including applying the side-filling resin composition onto the peripheral edge portion of the surface, facing the base member, of the mounted component; and
a curing step including curing the side-filling resin composition that has been applied,
the curing step further including irradiating the side-filling resin composition with light.
